(19) United States
(12) Patent Application Publication
(10) Pub. No.: US 2011/0024793 A1
(43) Pub. Date: Feb. 3, 2011

(54) BULK HETEROJUNCTION SOLAR CELL AND METHOD OF MANUFACTURING THE SAME

(76) Inventor: Chan Wook Jeon, Seoul (KR)

Correspondence Address: SHERR & VAUGHN, PLLC, 620 HERNDON PARKWAY, SUITE 320, HERNDON, VA, 20170, US

(21) Appl. No.: 12/935,330

(22) PCT Filed: Mar. 19, 2009
(86) PCT No.: PCT/KR09/01405

§ 371 Date: Sep. 29, 2010

(30) Foreign Application Priority Data
Mar. 31, 2008 (KR) 10-2008-0029664

(51) Int. Cl. H01L 31/0264

(52) U.S. Cl. 257/184; 438/94; 257/E31.004

(57) ABSTRACT

Provided are a bulk heterojunction solar cell, including: a substrate; a rear electrode formed on a top surface of the substrate; a core layer comprising a copper indium gallium diselenide (CIGS) layer in which a CIGS powder is formed on a top surface of the rear electrode to be porous, an n-type buffer layer coated on the CIGS powder, and an n-type ZnO layer coated on the n-type buffer layer; and a grid electrode formed on a top surface of the core layer, and a method of manufacturing the same. A porous p-type semiconductor layer is formed by sintering CIGS powders, and then, the n-type semiconductor is coated on the surface of the CIGS powders by using a wet method such that a much larger junction area than a physical size of the solar cell is formed and a power output of the solar cell can be greatly increased.

### TECHNICAL FIELD

The present invention relates to a bulk heterojunction solar cell and a method of manufacturing the same, and more particularly, to a bulk heterojunction solar cell in which a larger junction area than the area of a substrate is formed to maximize photoelectric conversion efficiency, and a method of manufacturing the same.

### BACKGROUND ART

I-III-VI₂ group chalcopyrite-based compound semiconductors that are generally represented as CuInSe₂ have a direct transition type energy band gap and have the highest light absorption coefficient of 1×10⁵ cm⁻¹. Thus, in the I-III-VI₂ group chalcopyrite-based compound semiconductors, high-efficiency solar cells can be manufactured with a thin film having a thickness of 1 to 2 μm, and long-term electro-optic stability is very excellent.

For this reason, the chalcopyrite-based compound semiconductors are being focused on as a material used in forming low-cost and high-efficiency solar cells that remarkably improve economic efficiency of photovoltaics by replacing currently-used high-cost crystalline silicon solar cells.

In addition, CuInSe₂ has a band gap of 1.04 eV and substitutes a portion of indium (In) by gallium (Ga) and a portion of selenium (Se) by sulfur (S) so as to adjust an idealistic band gap of 1.4 eV. For your reference, the band gap of CuGaSe₂ is 1.6 eV, and the band gap of CuGaS₂ is 2.5 eV.

A five-component compound that replaces a portion of In with Ga and a portion of Se with S is indicated by [Cu(InₓGa₁₋ₓ)(Se_{y}S_{1-y})₂] and is represented as copper indium diselenide (CIS) or copper indium gallium diselenide (CIGS). Hereinafter, such a compound is defined as CIGS.

Long-term reliability, which is one advantage of solar cells that uses CIGS to form a light absorption layer, has been proved that there is no change in efficiency even after ten years as a result of a long-term outdoor test that has started by the U.S. National Renewable Energy Laboratory (NREL) in November, 1988.

FIG. 1 is a cross-sectional view of a related solar cell that uses CIGS to form a light absorption layer. Referring to FIG. 1, the related solar cell that uses CIGS to form the light absorption layer is manufactured by sequentially forming five unit thin films such as a rear electrode 20, a light absorption layer 30, a buffer layer 40, a transparent electrode 50, and an antireflection film 60 on a substrate 10 that is generally formed of glass, and by forming a grid electrode 70.

Various methods of physically and chemically manufacturing a thin film may be used in various materials and their composition and a method of manufacturing the same according to unit thin films. If the area of a solar cell increases, photoelectric conversion efficiency is lowered due to an increase in a sheet resistance. Thus, a large-scale module is patterned so as to be connected in series at regular intervals.

Glass is generally used for the substrate 10. In addition, a ceramic substrate such as alumina, a metal substrate such as stainless steel or copper (Cu) tape or polymer may be used. Soda-lime glass with low cost is used as the glass substrate 10. Photoelectric conversion efficiency of 19.2% is obtained by the U.S. NREL by using a soda-lime glass substrate. In addition, flexible polymer such as polyimide or stainless sheet may be used for the substrate 10.

Nitrogen (Ni), copper (Cu), etc. are used for the rear electrode 20. Molybdenum (Mo) is most widely used for the rear electrode 20. This is because Mo has high electrical conductivity, an ohmic contact at CIGS and high-temperature stability under a Se atmosphere. A Mo thin film is mainly used by DC sputtering. The Mo thin film must have a low specific resistance as an electrode and must be susceptible to adhesion to the glass substrate so as to prevent peeling off due to a difference in thermal expansion coefficients.

In general, in CIGS solar cells, a CuInGaSe₂ thin film, which is a p-type semiconductor, and a zinc oxide (ZnO) thin film, which is an n-type semiconductor and is used as a window layer, constitute a pn-junction. In other words, the CuInGaSe₂ thin film is used as the light absorption layer 30, and the ZnO thin film is used as the transparent electrode 50. However, two materials have a large difference in both lattice constants and energy band gaps. Thus, in order to constitute a good junction, the buffer layer 40 in which a band gap is in the middle of the two materials is required.

Sulfuration cadmium (CdS) is used for the buffer layer 40 so as to form high-efficiency solar cells. A CdS thin film is formed as a thin film having a thickness of about 500 by using chemical bath deposition (CBD). The CdS thin film has an energy band gap of 2.46 eV, which corresponds to the wavelength of about 550 nm.

As described above, the CdS thin film is an n-type semiconductor and may have a low resistance by doping In, Ga, Al, etc into the CdS thin film. The drawback of CdS is that Cd itself is poisonous and a wet chemical process is used to form the CdS thin film unlike in other unit thin films. As an alternative to the wet chemical process, InₓSe_{y} may be manufactured by using a physical process of manufacturing a thin film.

CuInSe₂ that is a three-component compound and has been used for the light absorption layer 30 in the early of development, has an energy band gap of 1.04 eV and has a high short circuit current but has a low open voltage, which results in low efficiency. Thus, in order to increase an open voltage, a portion of In of CuInSe₂ is substituted by Ga or Se is substituted by S. CuInSe₂ has an energy band gap of about 1.5 eV, and the energy band gap of a Cu(InₓGa₁₋ₓ)Se₂ compound semiconductor to which Ga is added, may be adjusted according to the amount of Ga added.

However, when the energy band gap of the light absorption layer 30 is large, the open voltage increases. However, the short circuit current is reduced. Thus, it is required to adjust the content of Ga. In this way, the CIGS thin film is a multicomponent compound and thus, a process of manufacturing the same is very complicated.

Examples of physical methods of manufacturing the CIGS thin film which is the light absorption layer 30 include evaporation, sputtering and selenide, and there is electroplating as a chemical method of manufacturing the CIGS thin film. Various methods of manufacturing the CIGS thin film may be used according to types of starting materials including a metal, a two-component compound, etc.

The best efficiency can be obtained when using simultaneous evaporation that uses four metal elements Cu, In, Ga, and Se as the starting material. Unlike in related physical and chemical methods of manufacturing the CIGS thin film, nano-sized particles (powder, colloid, etc.) are synthesized on a Mo substrate, are mixed with a solvent and are screen-printed and reaction-sintered, thereby forming the light absorption layer 30.

The window layer which is an n-type semiconductor and in which a pn-junction with the CIGS thin film, is formed in front of a solar cell and acts as the transparent electrode 50. Thus, the window layer must have high light transmittance and good electrical conductivity. Currently-used ZnO has an energy band gap of about 3.3 eV and high light transmittance of about 80% or more. In addition, a low resistance of less than 10⁻⁴/cm can be obtained by doping Al or B into the ZnO thin film. When B is doped into the ZnO thin film, the light transmittance of a near infrared ray (IR) area increases, and the short circuit current increases.

Examples of RF sputtering methods for the ZnO thin film include a method of depositing the ZnO thin film by using a ZnO target, reactive sputtering using the ZnO target, and metalorganic chemical vapor deposition (MOCVD). A double structure in which an ITO thin film having an excellent electro-optic characteristic is deposited on the ZnO thin film may be adopted. A method of depositing an undoped i-type ZnO thin film on a CdS thin film and then, depositing an n-type ZnO thin film having a low resistance on the i-type ZnO thin film so as to improve the efficiency of a solar cell can be used.

Meanwhile, if the reflection loss of solar rays incident on the solar cell is reduced, the efficiency of the solar cell of about 1% can be improved. Thus, the antireflection film 60 is used. MgF₂ is used for the antireflection film 60. Electron beam evaporation is most widely used as a physical method of manufacturing a thin film.

In addition, the grid electrode 70 is used to collect a current at the surface of the solar cell, and Al or Ni/Al is generally used for the grid electrode 70. Solar rays are not absorbed into the area of the grid electrode 70, which results in a loss of efficiency. Thus, a precise design is needed.

Furthermore, the photoelectric conversion efficiency of the thin film solar cells having a restricted area is limited. Thus, in order to maximize the photoelectric conversion efficiency of a solar cell having the same area, the area of a pn-junction side must be increased.

However, in the related method of manufacturing the thin film, the pn-junction side is parallel to the plane of a substrate and thus, the area of the pn-junction side is larger than the area of the substrate. Therefore, higher photoelectric conversion efficiency compared to the pn-junction side cannot be obtained.

### DISCLOSURE OF INVENTION

### Technical Problem

The present invention provides a bulk heterojunction solar cell in which a conductive zinc oxide (ZnO) film as an n-type semiconductor is formed inside a copper indium gallium diselenide (CIGS) layer as a p-type semiconductor layer and a larger junction area than the area of a substrate is formed to maximize photoelectric conversion efficiency, and a method of manufacturing the same.

### Technical Solution

According to an aspect of the present invention, there is provided a bulk heterojunction solar cell, including: a substrate; a rear electrode formed on a top surface of the substrate; a core layer comprising a copper indium gallium diselenide (CIGS) layer in which a CIGS powder is formed on a top surface of the rear electrode to be porous, an n-type buffer layer coated on the CIGS powder, and an n-type ZnO layer coated on the n-type buffer layer; and a grid electrode formed on a top surface of the core layer.

The bulk heterojunction solar cell may further include a Al:ZnO nano-power layer formed on a top surface of the core layer.

The n-type buffer layer may include sulfuration cadmium (CdS).

The bulk heterojunction solar cell may further include a CIGS nano-powder layer formed on a bottom surface of the core layer.

The thickness of the CIGS layer may be 3 to 10 μm, the thickness of the n-type buffer layer may be 30 to 70 nm, the thickness of the n-type ZnO layer may be 200 to 300 nm, and the thickness of the CIGS nano-powder layer may be 0.2 to 0.3 μm.

According to another aspect of the present invention, there is provided a method of manufacturing a bulk heterojunction solar cell, including: coating a rear electrode on a top surface of a substrate; forming a copper indium gallium diselenide (CIGS) layer to be porous by sintering a CIGS powder on a top surface of the rear electrode; coating an n-type buffer layer on the CIGS powder by using chemical bath deposition (CBD); forming a core layer by coating the n-type ZnO layer on the n-type buffer layer by using CBD; and forming a grid electrode on a top surface of the core layer.

The method may further include, after the forming of the core layer, forming an Al:ZnO nano-powder layer on the top surface of the core layer.

The method may further include, after the coating of the rear electrode, forming a CIGS nano-powder layer on a bottom surface of the core layer.

The forming of the CIGS layer may be performed by heat treatment in a furnace of 350° C. to 450° C. under a Se atmosphere for 10 to 50 minutes.

The n-type buffer layer may include CdS, and the coating of the n-type buffer layer may include coating the n-type buffer layer by reacting CdCl₂ and thiourea (CH₄N₂S) on condition of pH=9 to 11 and 55° C. to 95° C. for 5 to 35 minutes.

The n-type ZnO layer may be Al:ZnO, and the forming of the core layer may include forming the core layer by reacting Al₂(SO₄)₃, ZnSO₄, and enthylene diamine on condition of pH=10 to 12 and 40° C. to 80° C. for 5 to 25 minutes and by coating the n-type ZnO layer on the n-type buffer layer.

The forming of the grid electrode may include forming the grid electrode at a side of the top surface of the core layer by depositing an Al/Ni double layer to a thickness of Al 200 to 400 nm and Ni 30 to 70 nm by using a shadow mask and evaporation.

### ADVANTAGEOUS EFFECTS

As described above, in the bulk heterojunction solar cell and the method of manufacturing the same according to the present invention, firstly, instead of forming a p-type semiconductor and an n-type semiconductor as a thin layer, a porous p-type semiconductor layer is formed by sintering CIGS powders, and then, the n-type semiconductor is coated on the surface of the CIGS powders by using a wet method such that a much larger junction area than a physical size of the solar cell is formed and a power output of the solar cell can be greatly increased. Secondly, when Al:ZnO as a conductive transparent electrode is formed by sputtering as a general method, Al:ZnO cannot be uniformly coated on the inside of the p-type semiconductor. However, according to the present invention, Al:ZnO is grown by using CBD such that ZnO/CdS can be uniformly coated on the entire surface of the CIGS powders by using the wet method. Thirdly, the solar cell can be manufactured under room pressure such that manufacturing costs can be remarkably reduced.

### BRIEF DESCRIPTION OF DRAWINGS

The above and other aspects of the present invention will become more

apparent by describing in detail exemplary embodiments thereof with reference to the attached drawings in which:

FIG. 1 is a cross-sectional view of a related solar cell that uses copper indium gallium diselenide (CIGS) as a light absorption layer;

FIG. 2 is a cross-sectional view of a bulk heterojunction solar cell according to an embodiment of the present invention;

FIG. 3 is a partially-enlarged cross-sectional view of a powder of a core layer of the bulk heterojunction solar cell illustrated in FIG. 2;

FIG. 4 is a cross-sectional view of a bulk heterojunction solar cell according to another embodiment of the present invention; and

FIG. 5 is a flowchart illustrating a method of manufacturing a bulk heterojunction solar cell according to an embodiment of the present invention.

### BEST MODE FOR CARRYING OUT THE INVENTION

The present invention will now be described more fully with reference to the accompanying drawings, in which exemplary embodiments of the invention are shown. First, terms or words used in the present specification and the claims should not be construed as being limited to general or literal meaning, and the inventor should construe his/her own invention in meaning and concept that coincide with the technical spirit of the invention based on the principle for properly defining the concept of the terms so as to describe his/her own invention in the best manner.

Thus, configurations shown in embodiments and the drawings of the present invention rather are an example of the most exemplary embodiment and does not represent all of the technical spirit of the invention. Thus, it will be understood that various equivalents and modifications that replace the configurations are possible when filing the present application.

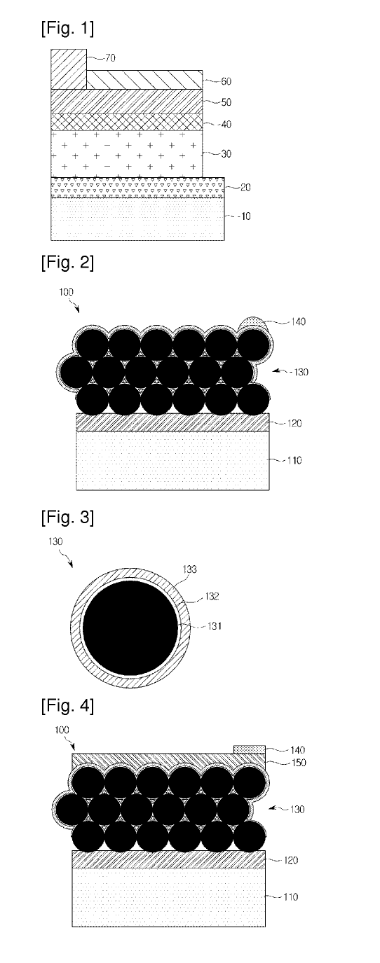

Hereinafter, a bulk heterojunction solar cell 100 according to an embodiment of the present invention and a method of manufacturing the same will now be described with reference to FIGS. 2 and 3.

FIG. 2 is a cross-sectional view of the bulk heterojunction solar cell 100, and FIG. 3 is a partially-enlarged cross-sectional view of a powder of a core layer of the bulk heterojunction solar cell 100 illustrated in FIG. 2.

The bulk heterojunction solar cell 100 includes a substrate 110, a rear electrode 120, a core layer 130, and a grid electrode 140.

The rear electrode 120 is coated on the top surface of the substrate 110, and the core layer 130 includes a copper indium gallium diselenide (CIGS) layer in which a CIGS powder 131 is formed on the top surface of the rear electrode 120 to be porous, an n-type buffer layer 132, which is coated on the CIGS power 131, and an n-type ZnO layer 133, which is coated on the n-type buffer layer 132. In addition, the grid electrode 140 is formed at a side of a top surface of the core layer 130.

Here, the n-type buffer layer 132 may include sulfuration cadmium (CdS).

In addition, if the rear electrode 120 and an n-type semiconductor layer that will be described later directly contact each other, a short circuit or shunt may be formed. In order to prevent formation of the short circuit or shunt, the core layer 130 may further include a copper indium diselenide (CIS) or CIGS nano-powder layer (not shown) having a diameter of 10 to 50 nm formed on its bottom surface.

In this case, the thickness of the CIGS layer may be 3 to 10 μm, and the thickness of the n-type buffer layer 132 may be 50 nm, and the thickness of the n-type ZnO layer 133 may be 200 to 300 nm, and the thickness of the CIGS nano-power layer (not shown) may be 0.2 to 0.3 μm.

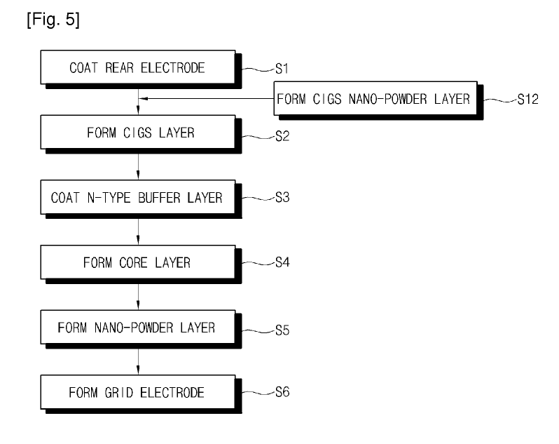

FIG. 5 is a flowchart illustrating a method of manufacturing a bulk heterojunction solar cell according to an embodiment of the present invention. Hereinafter, the method of manufacturing the bulk heterojunction solar cell will be described with reference to FIGS. 2 and 5 in detail.

The method of manufacturing the bulk heterojunction solar cell illustrated in FIG. 5 includes coating the rear electrode 120 (S1); forming the CIGS layer (S2); coating the n-type buffer layer 132 (S3); forming the coating layer 130 (S4); forming the grid electrode 140 (S6).

The coating of the rear electrode 120 (S1) includes coating the rear electrode 120 on the top surface of the substrate 110. Molybdenum (Mo) may be coated on the substrate 110 formed of soda-lime glass, as the rear electrode 120.

Next, the forming of the CIGS layer (S2) includes forming the CIGS layer by sintering the CIGS powder 131 on the top surface of the rear electrode 120.

First, the CIGS power 131 may be mixed with methanol or cellulose, may be coated on Mo coated on the soda-lime glass substrate by using a screen printing technique and then may be dried at a hot plate or an oven of 120° C. for 10 minutes. Here, the thickness of the coating may be adjusted by repeatedly performing screen printing and drying.

Furthermore, the method may further include, between the coating of the rear electrode 120 (S1) and the forming of the CIGS layer (S2), forming the CIGS nano-powder layer on the bottom surface of the core layer 130 (S12).

In other words, as described previously, if the rear electrode 120 and the n-type semiconductor layer directly contact each other, the short circuit or shunt may be formed. Thus, in order to prevent formation of the short circuit of shunt, the CIS or CIGS nano-powder layer having a diameter of 10 to 50 nm may be formed to a thickness of about 0.2 to 0.3 μm. In this case, generally-used CIS or CIGS nano-powder may be used.

Next, a process of manufacturing CIGS in the form of powder will be described.

In order to manufacture a CIGS compound, induction melting may be used. When four metal elements such as Cu, In, Ga, and Se having different melting points and different vapor pressures are molten, Cu having a high melting point is first molten and then In and Ga are added to molten Cu so as to continue melting. In particular, Se has a large vapor pressure and thus may be finally added to molten Cu. The amount of loss of evaporation is checked through experiments and overmeasure of Se is added to molten Cu.

Induction melting continues for an addition time of about 1 minute after addition of Se so as to manufacture a molten compound having a uniform composition. If induction melting stops, rapid cooling is performed. Thus, an ingot of the manufactured compound may have a comparatively uniform composition in the direction of a radius. The ingot is broken to a proper size and then is manufactured as fine powders having the diameter of 0.1 to 3 μm by using a powder manufacturing equipment such as a ball mill and is sorted using a sieve according to sizes.

In the forming of the CIGS layer (S2), a dried sample may be heat-treated in a furnace of about 450° C. under a Se atmosphere for 30 minutes so that a porous CIGS layer in which powders are combined with one another, can be formed to a thickness of about 3-10 μm. In FIG. 2, the CIGS powders 131 are connected to each other.

Next, the coating of the n-type buffer layer 132 (S3) includes coating the n-type buffer layer 132 on the CIGS powders 131 by using chemical bath deposition (CBD).

As described previously, the porous CIGS layer is a p-type semiconductor in the present invention, and in order to form a pn-junction, the n-type buffer layer 132 as an n-type semiconductor is coated to a thickness of about 50 nm by using CBD.

Here, the n-type buffer layer 132 may include CdS, and the coating of the n-type buffer layer 132 may include coating the n-type buffer layer 132 by reacting CdCl₂ of about 2.4 mM and thiourea (CH₄N₂S) of about 2.4 mM on condition of pH=10 and 75° C. for 20 minutes so as to obtain a uniform thin film.

For your reference, the porous CIGS layer allows penetration of a reaction component molten in a solution. Thus, powders that are disposed near the substrate 110 have the same CdS thin film, as illustrated in FIG. 2. The sample in which the CdS thin film is formed, is used to remove impurity particles by ultrasonic cleaning using distilled water. A finally-obtained CdS layer has a thickness of about 40 nm, and space for a CIGS porous layer is maintained.

Next, the forming of the core layer 130 (S4) includes forming the core layer 130 by coating the n-type ZnO layer 133 on the n-type buffer layer 132 by using CBD.

Solar rays absorbed into the CIGS layer generate a plurality of electron-hole pairs (EHPs) within the CIGS layer. Electrons that exist near the pn-junction flow through the CdS layer as the buffer layer 132 and move. The electrons are moved to the grid electrode 140 as an n-type electrode and are collected. In this case, in order to increase lateral spreading, a transparent conductive layer as the n-type ZnO layer 133 may be formed. Pn-junction suggested by the present invention has a circular or at least three-dimensional (3D) shape, as illustrated in FIG. 2, unlike in a related solar cell. Thus, a method of forming a 3D transparent conductive layer is required.

To this end, the n-type ZnO layer 133 uses Al:ZnO. In the forming of the core layer 130 (S4), Al₂(SO₄)₃ of about 1 mM, ZnSO₄ of 20 mM, and enthylene diamine of 45 mM as a ligand as a reaction counter material, respectively, are supplied, are reacted on condition of pH=11 and 60° C. for 15 minutes, and the n-type ZnO layer 133 having a thickness of about 200 to 300 nm is coated on the n-type buffer layer 132, thereby forming the core layer 130. A shape in which CdS/ZnO is uniformly coated on the entire surface of the CIGS powder 131 is shown in FIG. 3.

Next, the forming of the grid electrode 140 (S6) includes forming the grid electrode 140 at a side of the top surface of the core layer 130. In the forming of the grid electrode 140 (S6), an Al/Ni double layer may be deposited to a thickness of 300/50 nm by using a shadow mask and evaporation, thereby forming the grid electrode 140 at a side of the top surface of the core layer 130. General grid electrode patterns in which finger patterns are disposed at an interval of 2 mm may be used.

Hereinafter, a bulk heterojunction solar cell 100 according to another embodiment of the present invention and a method of manufacturing the same will be described with reference to FIGS. 4 and 5 in detail.

FIG. 4 is a cross-sectional view of the bulk heterojunction solar cell 100 according to another embodiment of the present invention, and FIG. 5 is a flowchart illustrating a method of manufacturing the bulk heterojunction solar cell 100 according to an embodiment of the present invention.

The bulk heterojunction solar cell 100 according to the current embodiment includes a substrate 110, a rear electrode 120, a core layer 130, a nano-powder layer 150, and a grid electrode 140.

Here, the substrate 110, the rear electrode 120, the core layer 130, and the grid electrode 140 of the bulk heterojunction solar cell 100 illustrated in FIG. 4 are the same as those of the bulk heterojunction solar cell 100 illustrated in FIG. 2. Thus, description thereof will be omitted.

The only difference is that, as illustrated in FIG. 4, the Al:ZnO nano-powder layer 150 is formed on the top surface of the core layer 130. The Al:ZnO nano-powder layer 150 having a diameter of about 50 to 100 nm is additionally formed to a thickness of 1 μm so that electrical conductivity of the transparent electrode layer as the n-type ZnO layer 133 can be greatly improved.

In addition, the method of manufacturing the bulk heterojunction solar cell according to another embodiment of the present invention includes: coating the rear electrode 120 (S1); forming the CIGS layer (S2); coating the n-type buffer layer 132 (S3); forming the coating layer 130 (S4); forming the nano-powder layer 150 (S5); forming the grid electrode 140 (S6).

Here, the coating of the rear electrode 120 (S1), the forming of the CIGS layer (S2), the coating of the n-type buffer layer 132 (S3), the forming of the coating layer 130 (S4), the forming of the nano-powder layer 150 (S5), and the forming of the grid electrode 140 (S6) of the method of manufacturing the bulk heterojunction solar cell according to the current embodiment are the same as those of the method of manufacturing the bulk heterojunction solar cell according to the previous embodiment. Thus, description thereof will be omitted.

The forming of the nano-powder layer 150 (S5) includes forming the Al:ZnO nano-powder layer on the top surface of the core layer 130 after the forming of the core layer 130 (S4).

The nano-powder layer 150 having the thickness of 1 μm may be formed by using a general method such as doctor blading or screen printing.

While this invention has been particularly shown and described with reference to exemplary embodiments thereof, it will be understood by those skilled in the art that various changes in form and details may be made therein without departing from the spirit and scope of the invention as defined by the appended claims.

### INDUSTRIAL APPLICABILITY

The bulk heterojunction solar cell and the method of manufacturing the same according to the present invention can be used to manufacture a solar cell with a high photoelectric conversion efficiency.

1. A bulk heterojunction solar cell, comprising:
a substrate;
a rear electrode formed on a top surface of the substrate;
a core layer comprising a copper indium gallium diselenide (CIGS) layer in which a CIGS powder is formed on a top surface of the rear electrode to be porous, an n-type buffer layer coated on the CIGS powder, and an n-type ZnO layer coated on the n-type buffer layer; and
a grid electrode formed on a top surface of the core layer.

2. The bulk heterojunction solar cell of claim 1, further comprising a Al:ZnO nano-power layer formed on a top surface of the core layer.

3. The bulk heterojunction solar cell of claim 1, wherein the n-type buffer layer comprises sulfuration cadmium (CdS).

4. The bulk heterojunction solar cell of claim 1, further comprising a CIGS nano-powder layer formed on a bottom surface of the core layer.

5. The bulk heterojunctiion solar cell of claim 4, wherein a thickness of the CIGS layer is 3 to 10 μm, a thickness of the n-type buffer layer is 30 to 70 nm, a thickness of the n-type ZnO layer is 200 to 300 nm, and a thickness of the CIGS nano-powder layer is 0.2 to 0.3 μm.

6. A method of manufacturing a bulk heterojunction solar cell, comprising:
coating a rear electrode on a top surface of a substrate;
forming a copper indium gallium diselenide (CIGS) layer to be porous by sintering a CIGS powder on a top surface of the rear electrode;
coating an n-type buffer layer on the CIGS powder by using chemical bath deposition (CBD);
forming a core layer by coating the n-type ZnO layer on the n-type buffer layer by using CBD; and
forming a grid electrode on a top surface of the core layer.

7. The method of claim 6, further comprising, after the forming of the core layer, forming an Al:ZnO nano-powder layer on the top surface of the core layer.

8. The method of claim 6, further comprising, after the coating of the rear electrode, forming a CIGS nano-powder layer on a bottom surface of the core layer.

9. The method of claim 6, wherein the forming of the CIGS layer is performed by heat treatment in a furnace of 350° C. to 450° C. under a Se atmosphere for 10 to 50 minutes.

10. The method of claim 6, wherein the n-type buffer layer comprises
sulfuration cadmium (CdS), and the coating of the n-type buffer layer comprises coating the n-type buffer layer by reacting CdCl₂ and thiourea (CH₄N₂S) on condition of pH=9 to 11 and 55° C. to 95° C. for 5 to 35 minutes.

11. The method of claim 6, wherein the n-type ZnO layer is Al:ZnO, and the forming of the core layer comprises forming the core layer by reacting Al₂(SO₄)₃, ZnSO₄, and enthylene diamine on condition of pH=10 to 12 and 40° C. to 80° C. for 5 to 25 minutes and by coating the n-type ZnO layer on the n-type buffer layer.

12. The method of claim 6, wherein the forming of the grid electrode comprises forming the grid electrode at a side of the top surface of the core layer by depositing an Al/Ni double layer to a thickness of Al 200 to 400 nm and Ni 30 to 70 nm by using a shadow mask and evaporation.
